(19) United States
(12) Patent Application Publication
(10) Pub. No.: US 2026/0076195 A1
(43) Pub. Date: Mar. 12, 2026

(54) COLD PLATE, A SEMICONDUCTOR SYSTEM INCLUDING THE COLD PLATE, AND A METHOD THEREOF

(71) Applicant: SAMSUNG ELECTRONICS CO., LTD., Suwon-si (KR)

(72) Inventor: Eduardo HERNANDEZ PACHECO, San Jose, CA (US)

(73) Assignee: SAMSUNG ELECTRONICS CO., LTD., Suwon-si (KR)

(21) Appl. No.: 19/300,245

(22) Filed: Aug. 14, 2025

Related U.S. Application Data
(60) Provisional application No. 63/691,861, filed on Sep. 6, 2024.

(51) Int. Cl. H01L 23/473; H01L 25/16

(52) U.S. Cl. CPC H10W 40/47; H10W 90/00

(57) ABSTRACT

A semiconductor system may include a semiconductor device and a cold plate on the semiconductor device in a first direction (e.g., upward or downward). The cold plate may include an outlet and a plurality of inlets connected to the outlet via respective distribution channels. The respective distribution channels may be configured to cool respective components of the semiconductor device.

### CROSS-REFERENCE TO RELATED APPLICATION

This application is based on and claims priority from U.S. Provisional Application No. 63/691,861, filed on Sep. 6, 2024, the disclosure of which is incorporated herein by reference in its entirety.

### BACKGROUND

### 1. Field

Embodiments of the present disclosure relate to a semiconductor system that includes a cold plate, and a method of performing cooling thereof.

### 2. Description of Related Art

Semiconductor devices may generate heat and require cooling. However, thermal management solutions of comparative embodiments have a problem of being unable to provide uniform cooling of the semiconductor devices. Therefore, hot spots of the semiconductor devices may be exacerbated.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Embodiments of the present disclosure may address the above problems and/or other problems.

According to some example embodiments of the present disclosure, a device may be provided. The device may include: a first inlet configured to receive a first portion of a working fluid, the working fluid configured to provide cooling; a second inlet configured to receive a second portion of the working fluid; an outlet configured to output the first portion and the second portion of the working fluid from the device; a first distribution channel that connects the first inlet and the outlet; and a second distribution channel that connects the second inlet and the outlet.

According to some example embodiments of the present disclosure, the first inlet is at a first side of the device, wherein the second inlet is at a second side of the device, opposite to the first side, and wherein the outlet is between the first inlet and the second inlet.

According to some example embodiments of the present disclosure, the outlet is in a first direction from the first inlet, and wherein the first distribution channel includes a channel that extends in a second direction and a third direction, wherein the second direction crosses the first direction, and the third direction is opposite to the second direction.

According to some example embodiments of the present disclosure, the outlet is in a first direction from the first inlet, wherein the first distribution channel includes a channel that extends in a second direction and a third direction, wherein the second direction crosses the first direction, and the third direction is opposite to the second direction, wherein the outlet is in a fourth direction from the second inlet, the fourth direction being opposite to the first direction, and wherein the second distribution channel includes a channel that extends in the second direction and the third direction.

According to some example embodiments of the present disclosure, the outlet is in a first direction from the first inlet, and wherein the first distribution channel includes: a first channel that extends in a second direction and a third direction, wherein the second direction crosses the first direction, and the third direction is opposite to the second direction; and a second channel that is connected to the first inlet by the first channel, the second channel extending in the first direction and a fourth direction that is opposite to the first direction.

According to some example embodiments of the present disclosure, the second distribution channel is symmetrical with respect to the first distribution channel.

According to some example embodiments of the present disclosure, a semiconductor system may be provided. The semiconductor system may include: a semiconductor device; and a cold plate on the semiconductor device and configured to cool the semiconductor device, wherein the cold plate includes: a first inlet configured to receive a first portion of a working fluid, the working fluid configured to cool the semiconductor device; a second inlet configured to receive a second portion of the working fluid; an outlet configured to output the first portion and the second portion of the working fluid from the cold plate; a first distribution channel that connects the first inlet and the outlet; and a second distribution channel that connects the second inlet and the outlet.

According to some example embodiments of the present disclosure, the semiconductor device includes: at least one semiconductor chip; and at least one photonic engine configured to send at least one optical signal to the at least one semiconductor chip, wherein the first distribution channel is configured to cool the at least one semiconductor chip and the at least one photonic engine via the first portion of the working fluid, and wherein the second distribution channel is configured to cool the at least one semiconductor chip and the at least one photonic engine via the second portion of the working fluid.

According to some example embodiments of the present disclosure, the semiconductor device includes: at least one semiconductor chip; and at least one photonic engine configured to send at least one optical signal to the at least one semiconductor chip, wherein the first distribution channel extends from the first inlet to the outlet such as to at least partially overlap with the at least one photonic engine and the at least one semiconductor chip, and wherein the second distribution channel extends from the second inlet to the outlet such as to at least partially overlap with the at least one photonic engine and the at least one semiconductor chip.

According to some example embodiments of the present disclosure, the first inlet is at a first side of the cold plate, wherein the second inlet is at a second side of the cold plate, opposite to the first side, and wherein the outlet is between the first inlet and the second inlet.

According to some example embodiments of the present disclosure, the outlet is in a first direction from the first inlet, and wherein the first distribution channel includes a channel that extends in a second direction and a third direction, wherein the second direction crosses the first direction, and the third direction is opposite to the second direction.

According to some example embodiments of the present disclosure, the outlet is in a first direction from the first inlet, wherein the first distribution channel includes a channel that extends in a second direction and a third direction, wherein the second direction crosses the first direction, and the third direction is opposite to the second direction, wherein the outlet is in a fourth direction from the second inlet, the fourth direction being opposite to the first direction, and wherein the second distribution channel includes a channel that extends in the second direction and the third direction.

According to some example embodiments of the present disclosure, the outlet is in a first direction from the first inlet, and wherein the first distribution channel includes: a first channel that extends in a second direction and a third direction, wherein the second direction crosses the first direction, and the third direction is opposite to the second direction; and a second channel that is connected to the first inlet by the first channel, the second channel extending in the first direction and a fourth direction that is opposite to the first direction.

According to some example embodiments of the present disclosure, the second distribution channel is symmetrical with respect to the first distribution channel.

According to some example embodiments of the present disclosure, a method may be provided. The method may include: supplying a first portion and a second portion of a working fluid into a first inlet and a second inlet of a cold plate, respectively; cooling a semiconductor device via the first portion of the working fluid in a first distribution channel of the cold plate, and via the second portion of the working fluid in a second distribution channel of the cold plate; and outputting the first portion and the second portion of the working fluid via an outlet of the cold plate, wherein the first distribution channel connects the first inlet and the outlet, and the second distribution channel connects the second inlet and the outlet.

According to some example embodiments of the present disclosure, the semiconductor device includes: at least one semiconductor chip; and at least one photonic engine configured to send at least one optical signal to the at least one semiconductor chip, wherein the first distribution channel is configured to cool the at least one semiconductor chip and the at least one photonic engine via the first portion of the working fluid, and wherein the second distribution channel is configured to cool the at least one semiconductor chip and the at least one photonic engine via the second portion of the working fluid.

According to some example embodiments of the present disclosure, the semiconductor device includes: at least one semiconductor chip; and at least one photonic engine configured to send at least one optical signal to the at least one semiconductor chip, wherein the first distribution channel extends from the first inlet to the outlet such as to at least partially overlap with the at least one photonic engine and the at least one semiconductor chip, and wherein the second distribution channel extends from the second inlet to the outlet such as to at least partially overlap with the at least one photonic engine and the at least one semiconductor chip.

According to some example embodiments of the present disclosure, the first inlet is at a first side of the cold plate, wherein the second inlet is at a second side of the cold plate, opposite to the first side, and wherein the outlet is between the first inlet and the second inlet.

According to some example embodiments of the present disclosure, the outlet is in a first direction from the first inlet, and wherein the first distribution channel includes a channel that extends in a second direction and a third direction, wherein the second direction crosses the first direction, and the third direction is opposite to the second direction.

According to some example embodiments of the present disclosure, the outlet is in a first direction from the first inlet, wherein the first distribution channel includes a channel that extends in a second direction and a third direction, wherein the second direction crosses the first direction, and the third direction is opposite to the second direction, wherein the outlet is in a fourth direction from the second inlet, the fourth direction being opposite to the first direction, and wherein the second distribution channel includes a channel that extends in the second direction and the third direction.

### BRIEF DESCRIPTION OF DRAWINGS

Example embodiments of the present disclosure will be more clearly understood from the following detailed description taken in conjunction with the accompanying drawings in which:

FIG. 1 illustrates a schematic side view of a semiconductor system according to an example embodiment of the present disclosure;

FIG. 2 illustrates a schematic top view of a semiconductor system according to an example embodiment of the present disclosure;

FIG. 3 illustrates a top view of a semiconductor device of a semiconductor system according to an example embodiment of the present disclosure;

FIG. 4 illustrates a schematic top view of a semiconductor system to show distribution channels of a cold plate, according to an example embodiment of the present disclosure;

FIG. 5 illustrates a schematic top view of the cold plate of the semiconductor system of FIG. 4 to show the distribution channels, according to an example embodiment of the present disclosure;

FIG. 6 illustrates a schematic top view of a semiconductor system to show distribution channels of a cold plate, according to an example embodiment of the present disclosure;

FIG. 7 illustrates a schematic top view of the cold plate of the semiconductor system of FIG. 6 to show the distribution channels, according to an example embodiment of the present disclosure;

FIG. 8 illustrates a schematic top view of a semiconductor system to show distribution channels of a cold plate, according to an example embodiment of the present disclosure;

FIG. 9 illustrates a schematic top view of the cold plate of the semiconductor system of FIG. 8 to show the distribution channels, according to an example embodiment of the present disclosure;

FIG. 10 illustrates an example of structure of distribution channels of a cold plate, according to an example embodiment of the present disclosure; and

FIG. 11 illustrates a flowchart for a method of performing cooling of a semiconductor system, according to an example embodiment of the present disclosure.

### DETAILED DESCRIPTION

Embodiments of the present disclosure described herein are example embodiments, and thus, the present disclosure is not limited thereto, and may be realized in various other forms. Each of the embodiments provided in the following description is not excluded from being associated with one or more features of another embodiment also provided herein or not provided herein but consistent with the present disclosure. For example, even if matters described in a specific example embodiment are not described in a different example embodiment, the matters may be understood as being related to or combined with the different example embodiment, unless otherwise mentioned in descriptions thereof. In addition, it should be understood that all descriptions of principles, aspects, examples, and embodiments of the present disclosure are intended to encompass structural and functional equivalents thereof. In addition, these equivalents should be understood as including not only currently well-known equivalents but also equivalents to be developed in the future, that is, all devices that perform the same functions regardless of the structures thereof.

It will be understood that when an element, component, layer, pattern, structure, region, or so on (hereinafter collectively “element”) of a semiconductor device (or semiconductor package) is referred to as being “on,” “connected to,” or “coupled to” another element the semiconductor device, it can be directly on, connected to, or coupled to the other element or an intervening element(s) may be present. In contrast, when an element of a semiconductor device is referred to as being “directly on,” “directly connected to,” or “directly coupled to” another element of the semiconductor device, there are no intervening elements present. Like numerals refer to like elements throughout the present disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions here below, the “left” element and the “right” element may also be referred to as a “first” element or a “second” element, respectively, as long as their structural relationship is clearly understood in the context of the descriptions. Similarly, the terms a “lower” element and an “upper” element may be respectively referred to as a “first” element and a “second” element to distinguish the two elements.

It will be understood that, although the terms “first,” “second,” “third,” “fourth,” “fifth,” “sixth,” etc., may be used herein to describe various elements, these elements should not be limited by these terms. These terms are only used to distinguish one element from another element. Thus, a first element discussed below could be termed a second element without departing from the scope of the present disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” or “equal” is used to compare a dimension of two or more elements, the term may cover a “substantially same”or “substantially equal”dimension.

It will be also understood that, when a method of manufacturing an apparatus or structure is described as including a plurality of steps or operations, a certain step or operation described as being performed later than another step or operation may be performed prior to or at the same time as the other step or operation unless the other step or operation is described as necessarily being performed prior to the step or operation. Further, the method may include additional steps or operations not mentioned in the description.

Many example embodiments are described herein with reference to cross-sectional views that are schematic illustrations of the embodiments (and intermediate structures). As such, variations from the shapes of the illustrations as a result of, for example, manufacturing techniques and/or tolerances are to be expected. Thus, the embodiments should not be construed as limited to the particular shapes of regions illustrated herein, and are to include deviations in shapes that result from, for example, manufacturing. Various regions illustrated in the figures are schematic in nature and their shapes may not be intended to illustrate the actual shape of a region of a device and are not intended to limit the scope of the present disclosure. Further, in the drawings, the sizes and relative sizes of layers and regions may be exaggerated for clarity.

For the sake of brevity, conventional elements, structures, or layers included in a semiconductor package including a connection pad, an adhesive layer, an isolation layer, a barrier metal pattern, a seed layer, etc. may or may not be described in detail herein. For example, descriptions of certain connection pads of a semiconductor chip connected to solder balls or bumps in a semiconductor package may be omitted herein when these structural elements are not related to certain features of the embodiments. Also, descriptions of materials forming well-known structural elements may be omitted herein when those materials are not relevant to certain features of the embodiments. Herein, the term “connection” between two structures or elements may refer to an electrical connection therebetween. For example, a connection between semiconductor chips, semiconductor packages, and/or semiconductor devices may refer to an electrical connection of a corresponding two or more elements to each other. The terms “coupled” and “connected” may have the same meaning and may be used interchangeably herein. Further, the term “isolation” between two structures or elements pertains to electrical insulation or separation therebetween. For example, isolation of wiring patterns from each other may mean that the wiring patterns are not electrically connected to each other.

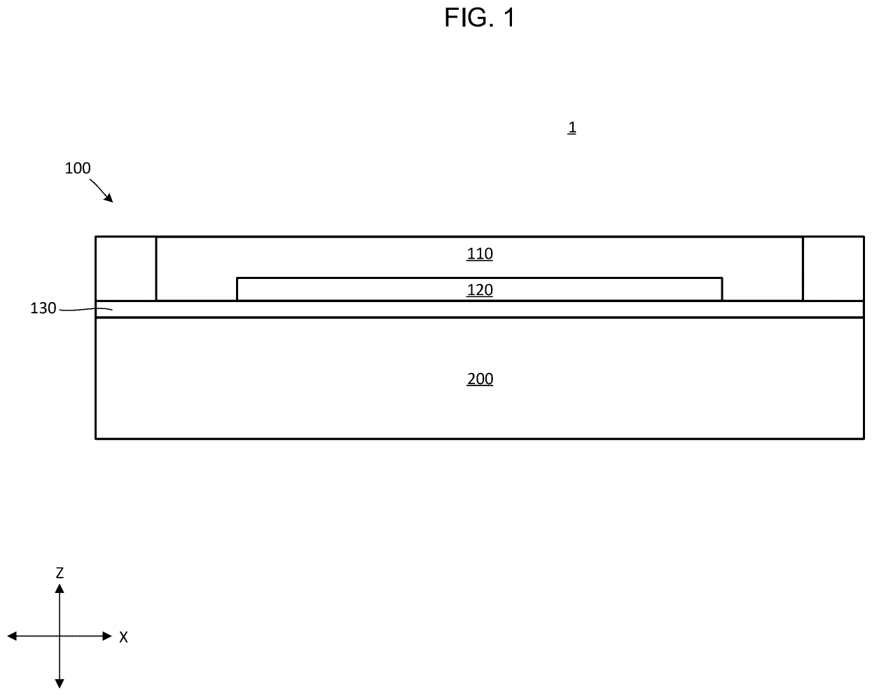

Hereinafter, various non-limiting example embodiments of the present disclosure are described with reference to FIGS. 1-11.

A liquid cooling cold plate of a comparative embodiment may include a body formed from a thermally conductive material (e.g., copper), and the body may include one inlet, one outlet, and an internal channel network system. A channel of the internal channel network system may have a serpentine shape. In such configuration, a working fluid (e.g., a coolant such as, for example, water) may enter the body via the inlet, move through the channel network system, collect or remove heat from a semiconductor device provided with the liquid cooling cold plate, and leave via the outlet. The liquid cooling cold plate may also be provided with a chiller, plumbing equipment, and sensors (e.g., pressure sensors and/or temperature sensors).

However, thermal design power (TDP) of co-packaged optics (CPO) is expected to reach about 1 kW. To dissipate heat of the CPOs, liquid cooling may be required. Due to configurations (e.g., semiconductor package symmetry) of the CPOs, the liquid cooling cold plate configuration of the comparative embodiment may not provide uniform cooling, which may therefore exacerbate hot spots of the CPOs.

For example, in the comparative embodiment, a component (e.g., a photonic engine) of the semiconductor device (e.g., a CPO) that is closer to the inlet will operate at a higher cooling performance as compared to other components (e.g., other photonic engines) of the semiconductor device that are located farther from the inlet such as, for example, at an opposite side of the semiconductor device. In order to achieve uniform cooling performance on both sides of the semiconductor device, a different cold plate configuration is required.

Example embodiments of the present disclosure may address the above problems and/or other problems.

According to some example embodiments of the present disclosure, a thermal management solution (e.g., a cold plate) may be provided that enables uniform cooling of a semiconductor device (e.g., a CPO package).

According to some example embodiments of the present disclosure, the thermal management solution (e.g., the cold plate) may have a topology that enhances cooling distribution of the semiconductor device (e.g., a CPO package).

According to some example embodiments of the present disclosure, the thermal management solution (e.g., the cold plate) may include multiple inlets and multiple outlets.

According to some example embodiments of the present disclosure, the semiconductor system may be provided and include the semiconductor device (e.g., a CPO package) and the thermal management solution (e.g., a cold plate).

According to some example embodiments of the present disclosure, uniform cooling of the semiconductor device (e.g., a CPO package), improved cooling performance for individual components (e.g., photonic engines) of the semiconductor device (e.g., a CPO package), and reduction of hot spot temperatures may be achieved.

For example, with reference to FIGS. 1-5, a semiconductor system 1 according to example embodiments of the present disclosure is described below.

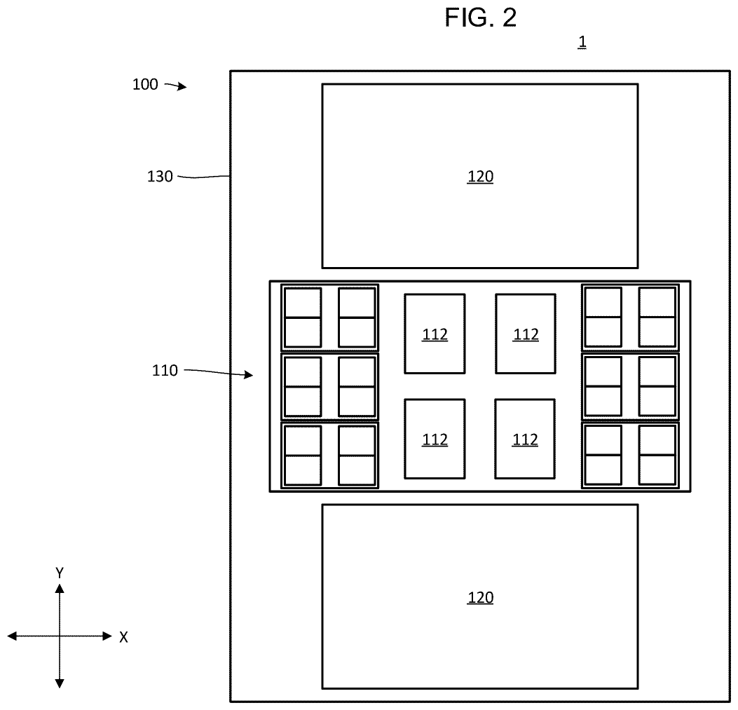

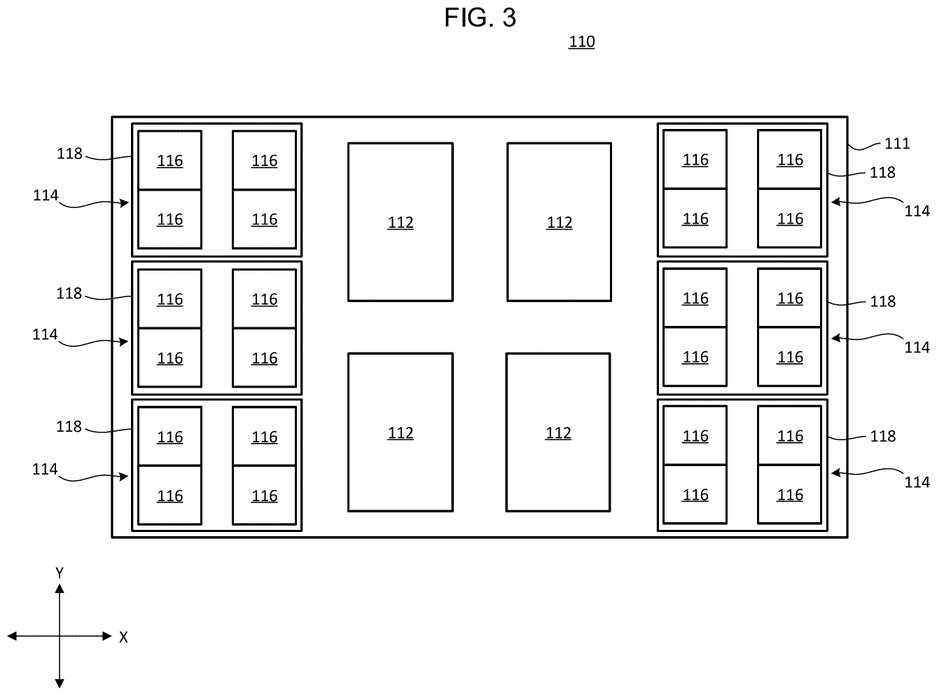

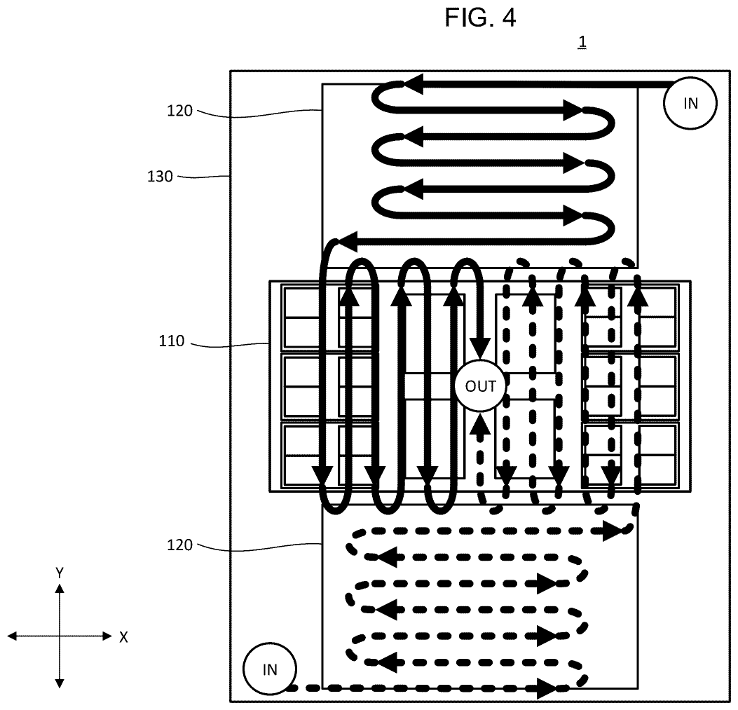

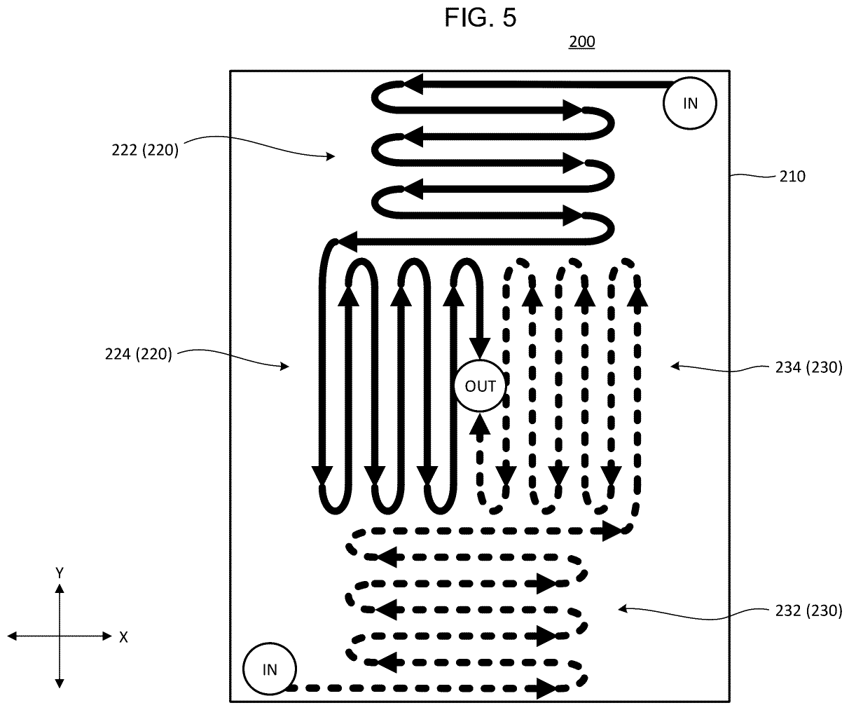

FIG. 1 illustrates a schematic side view of the semiconductor system 1 according to an example embodiment of the present disclosure. FIG. 2 illustrates a schematic top view of the semiconductor system 1 according to an example embodiment of the present disclosure. FIG. 3 illustrates a top view of a semiconductor device 100 of the semiconductor system 1 according to an example embodiment of the present disclosure. FIG. 4 illustrates a schematic top view of the semiconductor system 1 to show distribution channels of a cold plate 200, according to an example embodiment of the present disclosure. FIG. 5 illustrates a schematic top view of the cold plate 200 of the semiconductor system of FIG. 4 to show the distribution channels, according to an example embodiment of the present disclosure.

With reference to FIG. 1, the semiconductor system 1 may include the semiconductor device 100 and a cold plate 200 that is configured to cool the semiconductor device 100. The semiconductor device 100 (e.g., a semiconductor package) may overlap the cold plate 200 in a vertical direction (e.g., a Z-direction). For example, the semiconductor device 100 may be above the cold plate 200. For example, a bottom surface of the semiconductor device 100 may directly or indirectly contact a top surface of the cold plate 200. However, embodiments of the present disclosure are not limited thereto. For example, the cold plate 200 may be above the semiconductor device 100, and a bottom surface of the cold plate 200 may directly or indirectly contact a top surface of the semiconductor device 100.

In FIG. 1, the semiconductor device 100 and the cold plate 200 (and components thereof) are illustrated by rectangular boxes, respectively. However, shapes and sizes of the semiconductor device 100 and/or the cold plate 200 (and components thereof) are not limited by the illustration of FIG. 1.

With reference to FIG. 2, the semiconductor device 100 may be a CPO package. For example, the semiconductor device 100 may include a semiconductor sub-device 110, at least one photonic engine 120, and a substrate 130. The semiconductor sub-device 110 and the at least one photonic engine 120 may be on (e.g., mounted on) a top surface of the substrate 130. For example, a bottom surface of the semiconductor sub-device 110 and a bottom surface of the at least one photonic engine 120 may directly or indirectly contact the top surface of the substrate 130.

The substrate 130 may be configured to support the semiconductor sub-device 110 and the at least one photonic engine 120. The substrate 130 be, for example, an organic substrate, a silicon interposer, a redistribution layer (RDL) interposer, etc. According to some example embodiments of the present disclosure, the substrate 130 may be electrically connected to the semiconductor sub-device 110 and/or the at least one photonic engine 120 by at least one conductive path that is in and/or on the substrate 130. The at least one conductive path may be formed by an electrically conductive material.

The at least one photonic engine 120 may be a device configured to send and/or receive optical signals to and/or from the semiconductor sub-device 110. For example, the photonic engine 120 may include one or more from among an optical transceiver, a photonic integrated circuit (PIC), an optical switch, etc. For example, the at least one photonic engine 120 may be configured to communicatively connect the semiconductor sub-device 110 via, for example, fiber optic cables, to a device (e.g., a semiconductor device), that is external to the semiconductor sub-device 110.

The semiconductor sub-device 110 may be a semiconductor device (e.g., a semiconductor package) that includes at least one semiconductor chip. For example, the at least one semiconductor chip of the semiconductor sub-device 110 may be communicatively connected (e.g., electrically connected) to the at least one photonic engine 120 by the at least one conductive path of the substrate 130. Details of the semiconductor sub-device 110 are provided below with reference to FIG. 3.

As shown in FIG. 2, the semiconductor sub-device 110 may be provided on a center of the substrate 130 in a first horizontal direction (e.g., an X-direction) and/or a second horizontal direction (e.g., a Y-direction). However, embodiments of the present disclosure are not limited thereto. For example, the semiconductor sub-device 110 may be provided anywhere on the substrate 130, including at a side of the substrate 130 along the first horizontal axis (e.g., the X-axis) and/or the second horizontal direction (e.g., the Y-direction). According to some example embodiments of the present disclosure, two or more semiconductor sub-devices 110 may be positioned on the substrate 130 at various positions (e.g., the center and/or the side(s) of the substrate 130). For example, one or more of the semiconductor sub-devices 110 may be provided at one or both sides of the substrate 130 along the first horizontal axis (e.g., the X-axis), one or both sides of the substrate 130 along the second horizontal axis (e.g., the Y-axis), and/or at the center of the substrate along the first horizontal axis (e.g., the X-axis) and/or the second horizontal axis (e.g., the Y-axis).

As shown in FIG. 2, two photonic engines 120 may be provided. Each of the photonic engines 120 may be provided on the top surface of the substrate 130, at a respective side of the substrate 130 along the second horizontal axis (e.g., the Y-axis), such that the semiconductor sub-device 110 is between the two photonic engines 120 along the second horizontal axis (e.g., the Y-axis). However, embodiments of the present disclosure are not limited thereto. For example, only one photonic engine 120 may be provided, or three or more photonic engines 120 may be provided. Additionally, each of the one or more photonic engines 120 may be provided on the top surface of the substrate 130 on a same or different side of the substrate 130 along the first horizontal axis (e.g., the X-axis) and/or the second horizontal axis (e.g., the Y-axis), and/or may be provided at the center of the substrate 130 along the first horizontal axis (e.g., the X-axis) and/or the second horizontal axis (e.g., the Y-axis). For example, the one or more photonic engines 120 may be at one or more sides of the semiconductor sub-device 110 along the first horizontal axis (e.g., the X-axis) and/or the second horizontal axis (e.g., the Y-axis). For example, one or more of the photonic engines 120 may be provided at one or both sides of the substrate 130 along the first horizontal axis (e.g., the X-axis), one or both sides of the substrate 130 along the second horizontal axis (e.g., the Y-axis), and/or at the center of the substrate along the first horizontal axis (e.g., the X-axis) and/or the second horizontal axis (e.g., the Y-axis).

According to some embodiments of the present disclosure, the semiconductor device 100 may further include a dielectric that surrounds (e.g., encapsulates) one or more (e.g., some or all) from among the semiconductor sub-device 110 and the photonic engines 120 on the substrate 130.

With reference to FIG. 3, the semiconductor device 100 may include a substrate 111, at least one first semiconductor chip 112, and at least one memory device 114. The at least one first semiconductor chip 112 and the at least one memory device 114 may be on (e.g., mounted on) a top surface of the substrate 111. For example, a bottom surface of the at least one first semiconductor chip 112 and a bottom surface of the at least one memory device 114 may directly or indirectly contact the top surface of the substrate 111.

The substrate 111 may be configured to support the at least one first semiconductor chip 112 and the at least one memory device 114. The substrate 111 may include, for example, an organic substrate, a silicon interposer, a redistribution layer (RDL) interposer, etc. According to some example embodiments of the present disclosure, the substrate 111 may be electrically connected to the at least one first semiconductor chip 112 and/or the at least one memory device 114 by at least one conductive path that is in and/or on the substrate 111. The at least one conductive path may be formed by an electrically conductive material. According to some example embodiments of the present disclosure, the substrate 111 may be on (e.g., mounted on) the top surface of the substrate 130 (refer to FIG. 2). For example, a bottom surface of the substrate 111 may directly or indirectly contact the top surface of the substrate 130. The at least one conductive path of the substrate 111 and/or the at least one conductive path of the substrate 130 may enable the at least one first semiconductor chip 112 and/or the at least one memory device 114 to communicate with the at least one photonic engine 120. According to some example embodiments of the present disclosure, the substrate 111 may be omitted such that the at least one first semiconductor chip 112 and/or the at least one memory device 114 are on (e.g., mounted on) the substrate 130 without the substrate 111 therebetween.

According to some example embodiments of the present disclosure, each first semiconductor chip 112 may be a logic chip such as, for example, an accelerated processing unit (APU), central processing unit (CPU), graphics processing unit (GPU), application-specific integrated circuit (ASIC), a field programmable gate array (FPGA), etc.

According to some example embodiments of the present disclosure, each memory device 114 may be, for example, a high bandwidth memory (HBM) device.

According to some example embodiments of the present disclosure, each memory device 114 may include one or more of the second semiconductor chips 116. For example, as shown in FIG. 3, each of the memory devices 114 may include four stacks of the second semiconductor chips 116. However, embodiments of the present disclosure are not limited thereto. For example, each of the memory devices 111 may include only one stack, or three or more stacks, of the second semiconductor chips 116, and/or may include at least one second semiconductor chip 116 in a non-stacked arrangement. According to some example embodiments of the present disclosure, each of the second semiconductor chips 116 may be a dynamic random-access memory (DRAM) core die.

According to some example embodiments of the present disclosure, each memory device 114 may further include a third semiconductor chip 118. For example, a bottom surface of the third semiconductor chip 118 may directly or indirectly contact the top surface of the substrate 111, and the third semiconductor chip 118 may be electrically connected to the at least one first semiconductor chip 112 via the at least one conductive path that is in and/or on the substrate 111. The one or more second semiconductor chips 116 may be on (e.g., mounted on) a top surface of the third semiconductor chip 118. For example, a bottom surface of the one or more second semiconductor chips 116 may directly or indirectly contact the top surface of the third semiconductor chip 118, and the one or more second semiconductor chips 116 may be electrically connected to the at least one first semiconductor chip 112 via the third semiconductor chip 118 and the at least one conductive path that is in and/or on the substrate 111. According to some example embodiments of the present disclosure, the third semiconductor chip 118 may be a logic die. According to some embodiments of the present disclosure, the third semiconductor chip 118 may be omitted.

According to some embodiments of the present disclosure, each memory device 114 may further include a dielectric that surrounds (e.g., encapsulates) the second semiconductor chips 116 on the third semiconductor chip 118.

According to some embodiments of the present disclosure, the semiconductor sub-device 110 may further include a dielectric that surrounds (e.g., encapsulates) one or more (e.g., some or all) from among the first semiconductor chips 112 and the memory devices 114 on the substrate 111.

With reference to FIGS. 4-5, the cold plate 200 may be configured to cool the semiconductor sub-device 110 and the photonic engines 120 (refer to FIG. 2) via circulation of a working fluid (e.g., a coolant such as, for example, water) within distribution channels of the cold plate 200. In FIG. 4, a schematic top view of the semiconductor system 1 is shown, wherein illustration of distribution channels, inlets, and an outlet of the cold plate 200 is overlaid to demonstrate positional relationships of the semiconductor device 100 and the cold plate 200. As discussed above, the cold plate 200, and thus the channels, the inlets, and the outlet thereof, may be below or above the semiconductor device 100, including the semiconductor sub-device 110 and the photonic engines 120. In FIGS. 4-5, a flow direction of working fluid is shown with arrows.

The cold plate 200 may include a body 210 formed from a thermally conductive material (e.g., a metal such as, for example, copper). For example, the body 210 may have a plate shape. The cold plate 200 may further include, in the body 210, at least one inlet IN, at least one distribution channel, and at least one outlet OUT. The at least one inlet IN may be configured to introduce a working fluid into the body 210 of the cold plate 200, the at least one distribution channel may be configured to fluidly communicate the at least one inlet IN to the at least one outlet OUT, and the at least one outlet OUT may be configured to allow the working fluid to exit the cold plate 200. Accordingly, the working fluid may enter the at least one inlet IN, exchange heat with (e.g., receive heat from) the semiconductor device 100 through the body 210 such as to the cool the semiconductor sub-device 110 and/or the photonic engines 120, while moving in the at least one distribution channel, and exit the cold plate 200 via the at least one outlet OUT thereafter.

As shown in FIGS. 4-5, the cold plate 200 may include two inlets IN that are at opposite corners of the body 210. However, embodiments of the present disclosure are not limited thereto. For example, only one inlet IN may be provided, or three or more inlets IN may be provided. Additionally, each of the one or more inlets IN may be provided in the cold plate 200 at a same or different side of the body 210 along the first horizontal axis (e.g., the X-axis) and/or the second horizontal axis (e.g., the Y-axis), and/or may be provided at the center of the body 210 along the first horizontal axis (e.g., the X-axis) and/or the second horizontal axis (e.g., the Y-axis). For example, a number and a position(s) of the inlets IN may be selected based on positions of the semiconductor sub-device 110 and/or the photonic engines 120.

The cold plate 200 may also include a single outlet OUT at a center of the body 210 along the first horizontal axis (e.g., the X-axis) and/or the second horizontal axis (e.g., the Y-axis) as shown in FIGS. 4-5. However, embodiments of the present disclosure are not limited thereto. For example, two or more outlets OUT may be provided. Additionally, each of the one or more outlets ON may be provided in the cold plate 200 at a same or different side of the body 210 along the first horizontal axis (e.g., the X-axis) and/or the second horizontal axis (e.g., the Y-axis), and/or may be provided at the center of the body 210 along the first horizontal axis (e.g., the X-axis) and/or the second horizontal axis (e.g., the Y-axis). For example, a number and a position(s) of the outlets ON may be selected based on positions of the semiconductor sub-device 110 and/or the photonic engines 120.

The at least one distribution channel of the cold plate 200 may be a plurality of distribution channels. For example, a respective distribution channel may be provided for each inlet IN so as to communicatively connect the inlet IN to the at least one outlet OUT. For example, as shown in the FIGS. 4-5, the inlet IN at the upper-right corner of the body 210 may be connected to a first distribution channel 220 that is represented by a thick, solid line. Also, the inlet IN at the lower-left corner of the body 210 may be connected a second distribution channel 230 that is represented by a thick, dashed line. According to some embodiments of the present disclosure, the inlets IN, the at least one outlet OUT, the first distribution channel 220, and/or the second distribution 230 may be symmetrical arranged.

The first distribution channel 220 may include a first channel 222 and a second channel 224 downstream of the first channel 222. For example, the first channel 222 may communicatively connect the second channel 224 to the inlet IN at the upper-right corner of the body 210, and the second channel 224 may communicatively connect the first channel 222 to the outlet ON at the center of the body 210. The first channel 222 may be overlapped by at least one photonic engine 120 in the vertical direction (e.g., the Z-direction). For example, as shown in FIG. 4, the first channel 222 may be overlapped in the vertical direction (e.g., the Z-direction) by the photonic engine 120 at an upper side of the semiconductor sub-device 110 along the second horizontal axis (e.g., the Y-axis). Also, the second channel 224 may be overlapped in the vertical direction (e.g., the Z-direction) by at least a portion of the semiconductor sub-device 110. For example, as shown in FIG. 4, the second channel 224 may be overlapped in the vertical direction (e.g., the Z-direction) by a left portion of the semiconductor sub-device 110 along the second horizontal axis (e.g., the Y-axis). For example, with reference to FIGS. 3-5, the second channel 224 may be overlapped in the vertical direction (e.g., the Z-direction) by the memory devices 114 (e.g., the second semiconductor chips 116 and the third semiconductor chips 118) and the first semiconductor chips 112 of the left portion of the semiconductor sub-device 110.

As shown in FIGS. 4-5, the first channel 222 may have a serpentine shape that extends from the inlet IN to the second channel 224 by alternating in directions along the first horizontal axis (e.g., X-axis). The second channel 224 may have a serpentine shape that extends from the first channel 222 to the outlet OUT by alternating in directions along the second horizontal axis (e.g., the Y-axis). Alternatively, the first channel 222 may have a serpentine shape that extends from the inlet IN to the second channel 224 by alternating in directions along the second horizontal axis (e.g., the Y-axis), and/or the second channel 224 may have a serpentine shape that extends from the first channel 222 to the outlet OUT by alternating in directions along the first horizontal axis (e.g., the X-axis). However, embodiments of the present disclosure are not limited thereto. For example, the first channel 222 and/or the second channel 224 may have various shapes.

The second distribution channel 230 may include a third channel 232 and a fourth channel 234 downstream of the third channel 232. For example, the third channel 232 may communicatively connect the fourth channel 234 to the inlet IN at the lower-left corner of the body 210, and the fourth channel 234 may communicatively connect the third channel 232 to the outlet ON at the center of the body 210. The third channel 232 may be overlapped in the vertical direction (e.g., the Z-direction) by at least one photonic engine 120. For example, as shown in FIG. 4, the third channel 232 may be overlapped in the vertical direction (e.g., the Z-direction) by the photonic engine 120 at a lower side of the semiconductor sub-device 110 along the second horizontal axis (e.g., the Y-axis). Also, the fourth channel 234 may be overlapped by at least a portion of the semiconductor sub-device 110. For example, as shown in FIG. 4, the fourth channel 234 may be overlapped by a right portion of the semiconductor sub-device 110 along the second horizontal axis (e.g., the Y-axis). For example, with reference to FIGS. 3-5, the fourth channel 234 may be overlapped in the vertical direction (e.g., the Z-direction) by the memory devices 114 (e.g., the second semiconductor chips 116 and the third semiconductor chips 118) and the first semiconductor chips 112 of the right portion of the semiconductor sub-device 110.

As shown in FIGS. 4-5, the third channel 232 may have a serpentine shape that extends from the inlet IN to the fourth channel 234 by alternating in directions along the first horizontal axis (e.g., X-axis). The fourth channel 234 may have a serpentine shape that extends from the third channel 232 to the outlet OUT by alternating in directions along the second horizontal axis (e.g., the Y-axis). Alternatively, the third channel 232 may have a serpentine shape that extends from the inlet IN to the fourth channel 234 by alternating in directions along the second horizontal axis (e.g., the Y-axis), and/or the fourth channel 234 may have a serpentine shape that extends from the third channel 232 to the outlet OUT by alternating in directions along the first horizontal axis (e.g., the X-axis). However, embodiments of the present disclosure are not limited thereto. For example, the third channel 232 and/or the fourth channel 234 may have various shapes.

According to the configuration of the first distribution channel 220 and the second distribution channel 230, the first distribution channel 220 and the second distribution channel 230 may first pass below (or above) the photonic engines 120 and then below (or above) one or more of the memory devices 114 and the first semiconductor chips 112. Accordingly, working fluid in the first distribution channel 220 and the second distribution channel 230 may first cool the photonic engines 120 and then cool one or more of the memory devices 114 and the first semiconductor chips 112. Thus, the cold plate 200 may provide a balanced flow distribution in consideration of stricter thermal requirements that the photonic engines 120 may have in comparison to the thermal requirements of the memory devices 114 and the first semiconductor chips 112.

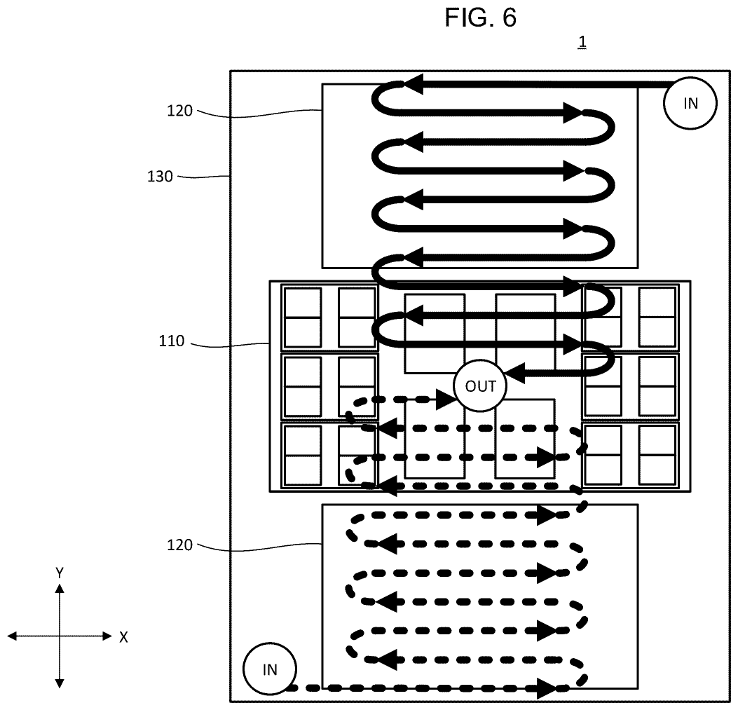

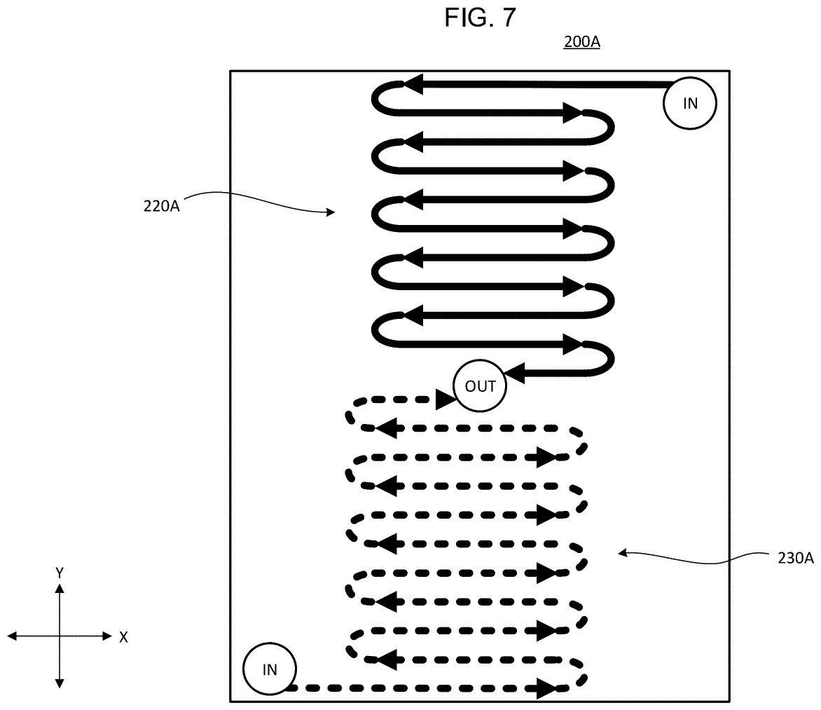

With reference to FIGS. 6-7, the semiconductor system 1 may include a cold plate 200A, instead of the cold plate 200. FIG. 6 illustrates a schematic top view of a semiconductor system to show distribution channels of the cold plate 200A, according to an example embodiment of the present disclosure; and FIG. 7 illustrates a schematic top view of the cold plate 200A of the semiconductor system of FIG. 6 to show the distribution channels, according to an example embodiment of the present disclosure. The cold plate 200A may be the same or similar to the cold plate 200, except for a configuration of distribution channels. Accordingly, the below description focuses on the differences thereof, and duplicate description may be omitted. In FIGS. 6-7, a flow direction of working fluid is shown with arrows.

As shown in FIGS. 6-7, the inlet IN at the upper-right corner of the body 210 may be connected to a first distribution channel 220A that is represented by a thick, solid line. Also, the inlet IN at the lower-left corner of the body 210 may be connected a second distribution channel 230A that is represented by a thick, dashed line.

The first distribution channel 220A may communicatively connect the inlet IN at the upper-right corner of the body 210 to the outlet ON at the center of the body 210. The first distribution channel 220A may be overlapped by at least one photonic engine 120 in the vertical direction (e.g., the Z-direction). For example, as shown in FIG. 6, the first distribution channel 220A may be overlapped in the vertical direction (e.g., the Z-direction) by the photonic engine 120 at an upper side of the semiconductor sub-device 110 along the second horizontal direction (e.g., the Y-axis). Also, the first distribution channel 220A may be overlapped in the vertical direction (e.g., the Z-direction) by at least a portion of the semiconductor sub-device 110. For example, as shown in FIG. 5, the first distribution channel 220A may be overlapped in the vertical direction (e.g., the Z-direction) by an upper portion of the semiconductor sub-device 110 along second horizontal axis (e.g., the Y-axis). For example, with reference to FIGS. 3 and 6, the first distribution channel 220A may be overlapped in the vertical direction (e.g., the Z-direction) by the memory devices 114 (e.g., the second semiconductor chips 116 and the third semiconductor chips 118) and the first semiconductor chips 112 of the upper portion of the semiconductor sub-device 110.

As shown in FIGS. 6-7, the first distribution channel 220A may have a serpentine shape that extends from the inlet IN to the outlet OUT by alternating in directions along the first horizontal axis (e.g., the X-axis). Alternatively, the first distribution channel 220A may have a serpentine shape that extends from the inlet IN to the outlet OUT by alternating in directions along the second horizontal axis (e.g., the Y-axis).

The second distribution channel 230A may communicatively connect the inlet IN at the lower-left corner of the body 210 to the outlet ON at the center of the body 210. The second distribution channel 230A may be overlapped in the vertical direction (e.g., the Z-direction) by at least one photonic engine 120. For example, as shown in FIG. 6, the second distribution channel 230A may be overlapped in the vertical direction (e.g., the Z-direction) by the photonic engine 120 at an lower side of the semiconductor sub-device 110 along the second horizontal axis (e.g., the Y-axis). Also, the second distribution channel 230A may be overlapped in the vertical direction (e.g., the Z-direction) by at least a portion of the semiconductor sub-device 110. For example, as shown in FIG. 6, the second distribution channel 230A may be overlapped in the vertical direction (e.g., the Z-direction) by a lower portion of the semiconductor sub-device 110 along the second horizontal axis (e.g., the Y-axis). For example, with reference to FIGS. 3 and 6, the second distribution channel 230A may be overlapped in the vertical direction (e.g., the Z-direction) by the memory devices 114 (e.g., the second semiconductor chips 116 and the third semiconductor chips 118) and the first semiconductor chips 112 of the upper portion of the semiconductor sub-device 110.

As shown in FIGS. 6-7, the second distribution channel 230A may have a serpentine shape that extends from the inlet IN to the outlet OUT by alternating in directions along the first horizontal axis (e.g., the X-axis). Alternatively, the second distribution channel 230A may have a serpentine shape that extends from the inlet IN to the outlet OUT by alternating in directions along the second horizontal axis (e.g., the Y-axis).

According to the configuration of the first distribution channel 220A and the second distribution channel 230A, the first distribution channel 220A and the second distribution channel 230A may first pass below (or above) the photonic engines 120 and then below (or above) one or more of the memory devices 114 and the first semiconductor chips 112. Accordingly, working fluid in the first distribution channel 220A and the second distribution channel 230A may first cool the photonic engines 120 and then cool one or more of the memory devices 114 and the first semiconductor chips 112. Thus, the cold plate 200A may provide a balanced flow distribution in consideration of stricter thermal requirements that the photonic engines 120 may have in comparison to the thermal requirements of the memory devices 114 and the first semiconductor chips 112.

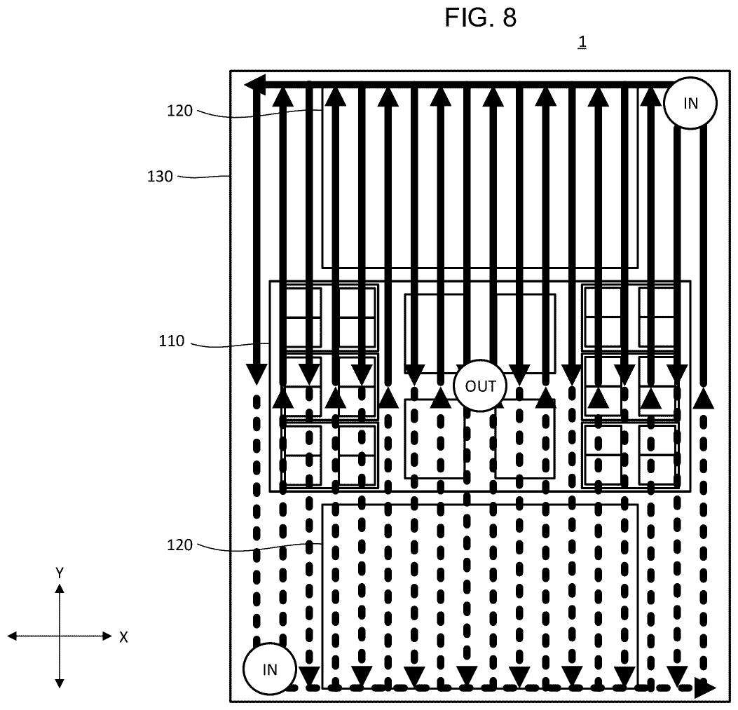

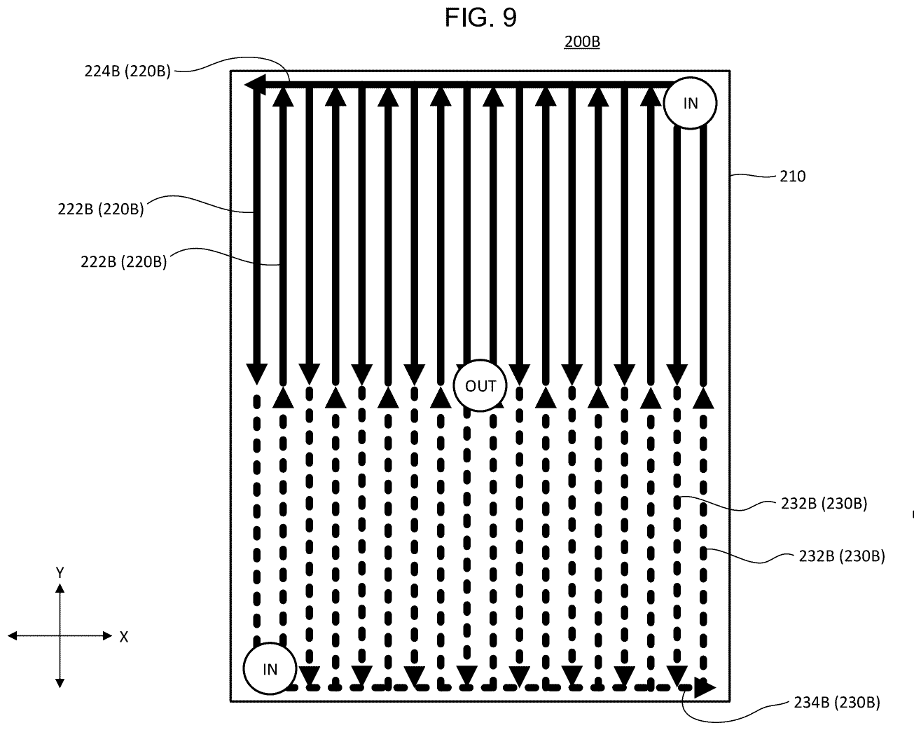

With reference to FIGS. 8-9, the semiconductor system 1 may include a cold plate 200B, instead of the cold plate 200. FIG. 8 illustrates a schematic top view of a semiconductor system to show distribution channels of the cold plate 200B, according to an example embodiment of the present disclosure; and FIG. 9 illustrates a schematic top view of the cold plate 200B of the semiconductor system of FIG. 8 to show the distribution channels, according to an example embodiment of the present disclosure. The cold plate 200B may be the same or similar to the cold plate 200, except for a configuration of distribution channels. Accordingly, the below description focuses on the differences thereof, and duplicate description may be omitted. In FIGS. 8-9, a flow direction of working fluid is shown with arrows.

As shown in FIGS. 8-9, the inlet IN at the upper-right corner of the body 210 may be connected to a first distribution channel 220B that is represented by a thick, solid line. Also, the inlet IN at the lower-left corner of the body 210 may be connected a second distribution channel 230B that is represented by a thick, dashed line.

The first distribution channel 220B may communicatively connect the inlet IN at the upper-right corner of the body 210 to the outlet ON at the center of the body 210. The first distribution channel 220B may be overlapped by at least one photonic engine 120 in the vertical direction (e.g., the Z-direction). For example, as shown in FIG. 8, the first distribution channel 220A may be overlapped in the vertical direction (e.g., the Z-direction) by the photonic engine 120 at an upper side of the semiconductor sub-device 110 in the second horizontal direction (e.g., the Y-axis). Also, the first distribution channel 220B may be overlapped in the vertical direction (e.g., the Z-direction) by at least a portion of the semiconductor sub-device 110. For example, as shown in FIG. 8, the first distribution channel 220A may be overlapped in the vertical direction (e.g., the Z-direction) by an upper portion of the semiconductor sub-device 110 along second horizontal axis (e.g., the Y-axis). For example, with reference to FIGS. 3 and 8, the first distribution channel 220A may be overlapped in the vertical direction (e.g., the Z-direction) by the memory devices 114 (e.g., the second semiconductor chips 116 and the third semiconductor chips 118) and the first semiconductor chips 112 of the upper portion of the semiconductor sub-device 110.

As shown in FIGS. 8-9, the first distribution channel 220B may include a plurality of first channels 222B that extend along the second horizontal axis (e.g., the Y-axis), and are separated from each other along the first horizontal axis (e.g., the X-axis). The first channels 222B may be alternatively arranged such that a flow direction of each first channel 222B along the second horizontal axis (e.g., the Y-axis) is opposite to neighboring ones of the first channels 222B. According to some example embodiments of the present disclosure, the first distribution channel 220B may further include at least one second channel 224B at an upper side and/or a lower side (e.g., at a center of the body 210) of the first channels 222B along the second horizontal axis (e.g., the Y-axis). The at least one second channel 224B may extend in a direction along the first horizontal axis (e.g., the X-axis) and communicatively connect the first channels 222B to each other. Alternatively, the first channels 222B may extend along the first horizontal axis (e.g., the X-axis) and may be separated from each other along the second horizontal axis (e.g., the Y-axis), and the at least one second channel 224B may extend in a direction along the second horizontal axis (e.g., the Y-axis).

The second distribution channel 230B may communicatively connect the inlet IN at the lower-left corner of the body 210 to the outlet ON at the center of the body 210. The second distribution channel 230B may be overlapped in the vertical direction (e.g., the Z-direction) by at least one photonic engine 120. For example, as shown in FIG. 8, the second distribution channel 230B may be overlapped in the vertical direction (e.g., the Z-direction) by the photonic engine 120 at an lower side of the semiconductor sub-device 110 along the second horizontal axis (e.g., the Y-axis). Also, the second distribution channel 230B may be overlapped in the vertical direction (e.g., the Z-direction) by at least a portion of the semiconductor sub-device 110. For example, as shown in FIG. 8, the second distribution channel 230B may be overlapped in the vertical direction (e.g., the Z-direction) by a lower portion of the semiconductor sub-device 110 along the second horizontal axis (e.g., the Y-axis). For example, with reference to FIGS. 3 and 8, the second distribution channel 230B may be overlapped in the vertical direction (e.g., the Z-direction) by the memory devices 114 (e.g., the second semiconductor chips 116 and the third semiconductor chips 118) and the first semiconductor chips 112 of the upper portion of the semiconductor sub-device 110.

As shown in FIGS. 8-9, the second distribution channel 230B may include a plurality of third channels 232B that extend along the second horizontal axis (e.g., the Y-axis), and are separated from each other along the first horizontal axis (e.g.,. the X-axis). The third channels 232B may be alternatively arranged such that a flow direction of each third channel 232B along the second horizontal axis (e.g., the Y-axis) is opposite to neighboring ones of the third channels 232B. According to some example embodiments of the present disclosure, the second distribution channel 230B may further include at least one fourth channel 234B at an upper side (e.g., at a center of the body 210) and/or a lower side of the third channels 232B along the second horizontal axis (e.g., the Y-axis). The at least one fourth channel 234B may extend in a direction along the first horizontal axis (e.g., the X-axis), and may communicatively connect the third channels 232B to each other. Alternatively, the third channels 232B may extend along the first horizontal axis (e.g., the X-axis) and may be separated from each other along the second horizontal axis (e.g., the Y-axis), and the at least one fourth channel 234B may extend in a direction along the second horizontal axis (e.g., the Y-axis).

According to the configuration of the first distribution channel 220B and the second distribution channel 230B, the cold plate 200B may provide a balanced flow distribution in consideration of stricter thermal requirements that the photonic engines 120 may have in comparison to the thermal requirements of the memory devices 114 and the first semiconductor chips 112.

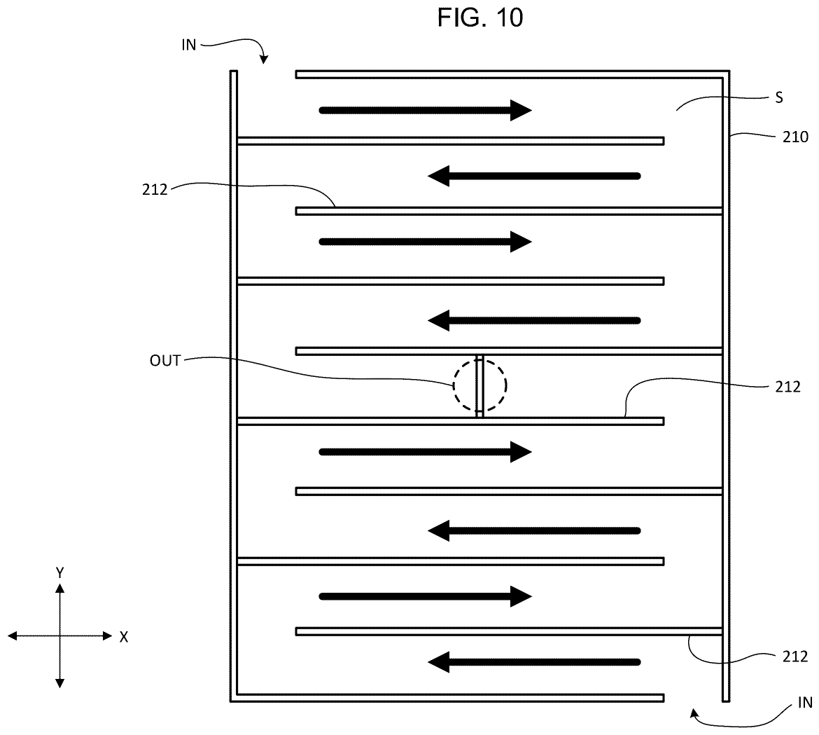

With reference to FIG. 10, example structure of the first distribution channels (e.g., the first distribution channels 220, 220A, and 220B) and the second distribution channels (e.g., the second distribution channels 230, 230A, and 230B) of the cold plate (e.g., the cold plates 200, 200A, and 200B) is described below.

According to some example embodiments of the present disclosure, the body 210 of the cold plate (e.g., the cold plates 200, 200A, and 200B) may include an internal space S. A shape of the internal space S may be defined by and between internal walls 212 (e.g., internal surfaces) of the body 210. By configuring the internal walls 212 (e.g., internal surfaces) of the body 210 with a particular arrangement, orientation, and/or shape, the first distribution channels (e.g., the first distribution channels 220, 220A, and 220B) and/or the second distribution channels (e.g., the second distribution channels 230, 230A, and 230B) of the cold plate (e.g., the cold plates 200, 200A, and 200B) may be formed. As an example, FIG. 9 shows a configuration of the internal walls 212 that may substantially correspond to the first distribution channel 220A and the second distribution channel 230A shown in FIG. 7.

According to some example embodiments of the present disclosure, the at least one inlet IN and the at least one outlet OUT may be defined by respective openings in the body 210 of the cold plate. For example, the respective openings may extend through any outer surface of the body 210 including, for example, one or more outer surfaces facing in directions along the first horizontal axis (e.g., the X-axis), the second horizontal axis (e.g., the Y-axis), and/or the vertical axis (e.g., the Z-axis).

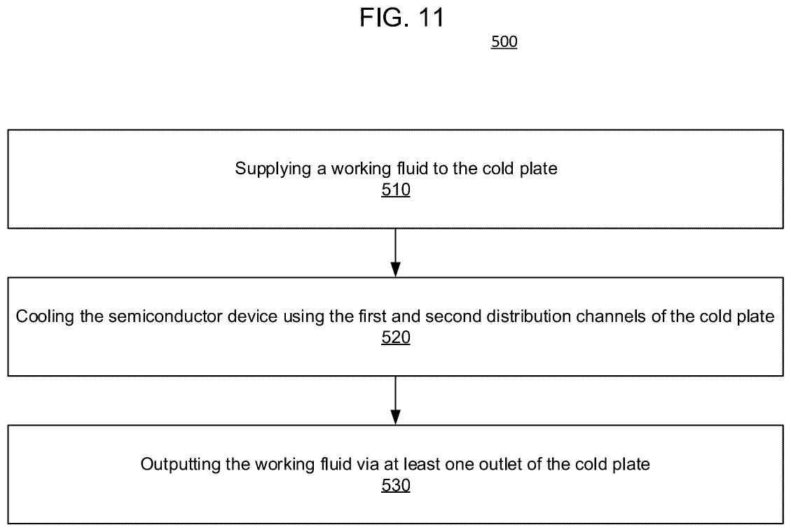

With reference to FIG. 11, a method 500 of performing cooling of the semiconductor system 1 may be provided. FIG. 11 illustrates a flowchart for the method 500 according to an example embodiment of the present disclosure.

For example, the method 500 may include supplying a working fluid (e.g., a coolant such as, for example, water) into the at least one inlet IN of the body 210 of the cold plate (operation 510); cooling the semiconductor device 100 by the working fluid receiving heat from the semiconductor device 100 while travelling in the first distribution channels (e.g., the first distribution channels 220, 220A, and 220B) and/or the second distribution channels (e.g., the second distribution channels 230, 230A, and 230B) of the cold plate (operation 520); and outputting the working fluid via the at least one outlet OUT of the body 210 of the cold plate (operation 530).

According to some embodiments of the present disclosure, the operations 510, 520, and/or 530 may be performed based on control of one or more pumps that is configured to supply the working fluid to and/or from the cold plate 200.

In the operation 520, the cooling may be performed using, for example, the first distribution channels (e.g., the first distribution channels 220, 220A, and 220B) and/or the second distribution channels (e.g., the second distribution channels 230, 230A, and 230B) described above with reference to FIGS. 1-9. Accordingly, a balanced flow distribution may be provided, and hot spots of the semiconductor device 100 may be minimized or avoided.

The present disclosure is presented to enable one of ordinary skill in the art to make and use the present disclosure and to incorporate it in the context of particular applications. While the foregoing is directed to specific examples, other and further examples may be devised without departing from the scope of the present disclosure.

Various modifications, as well as a variety of uses in different applications will be readily apparent to those skilled in the art, and the general principles defined herein may be applied to a wide range of embodiments. Thus, the present disclosure is not intended to be limited to the example embodiments presented herein, and is to be accorded the widest scope consistent with the principles and novel features disclosed herein.

In the description provided, numerous specific details are set forth in order to provide a more thorough understanding of the present disclosure. However, it will be apparent to one skilled in the art that the present disclosure may be practiced without necessarily being limited to these specific details. In other instances, well-known structures and devices are shown in block diagram form, rather than in detail, in order to avoid obscuring the present disclosure.

All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Various features are described in the present disclosure with reference to the drawings. It should be noted that the drawings are only intended to facilitate the description of the features. They are not intended as an exhaustive description of the present disclosure or as a limitation on the scope of the present disclosure. In addition, an illustrated example need not have all the aspects or advantages shown. An aspect or an advantage described in conjunction with a particular example is not necessarily limited to that example and can be practiced in any other examples even if not so illustrated, or if not so explicitly described.

Furthermore, any element in a claim that does not explicitly state “means for” performing a specified function, or “step for” performing a specific function, is not to be interpreted as a “means” or “step” clause as specified in 35 U.S.C. § 112(f). In particular, the use of “step of” or “act of” in the claims herein is not intended to invoke the provisions of 35 U.S.C. § 112(f).

The labels “left,” “right,” “front,” “back,” “top,” “bottom,” “forward,” “reverse,” “clockwise” and “counter clockwise,” if used, have been used for convenience purposes only and are not intended to imply any particular fixed direction. Instead, they are used to reflect relative locations and/or directions between various portions of an object.

While embodiments have been described with respect to circuit functions, the embodiments of the present disclosure are not limited. Possible implementations, may be embodied in a single integrated circuit, a multi-chip module, a single card, system-on-a-chip, or a multi-card circuit pack. As would be apparent to one skilled in the art, the various embodiments might also be implemented as part of a larger system. Such embodiments might be employed in conjunction with, for example, a digital signal processor, microcontroller, field-programmable gate array, application-specific integrated circuit, or general-purpose computer.

For the sake of brevity, conventional elements to semiconductor devices may or may not be described in detail herein. However, even if a certain element is described or illustrated in a semiconductor device in the present disclosure, the element may not be included in a claimed semiconductor device unless the element is recited as being included in the claimed semiconductor device. Also, when a particular method for deposition or etching used in manufacturing a semiconductor device is or is not mentioned herein, it will be understood that a conventional method for such deposition or etching may be applied in corresponding steps of manufacturing the semiconductor device.

While non-limiting example embodiments have been described above in connection with the drawings, it will be apparent to those skilled in the art that modifications and variations could be made without departing from the scope of the present disclosure.

What is claimed is:

1. A device comprising:
a first inlet configured to receive a first portion of a working fluid, the working fluid configured to provide cooling;
a second inlet configured to receive a second portion of the working fluid;
an outlet configured to output the first portion and the second portion of the working fluid from the device;
a first distribution channel that connects the first inlet and the outlet; and
a second distribution channel that connects the second inlet and the outlet.

2. The device of claim 1, wherein the first inlet is at a first side of the device,
wherein the second inlet is at a second side of the device, opposite to the first side, and
wherein the outlet is between the first inlet and the second inlet.

3. The device of claim 1, wherein the outlet is in a first direction from the first inlet, and
wherein the first distribution channel comprises a channel that extends in a second direction and a third direction, wherein the second direction crosses the first direction, and the third direction is opposite to the second direction.

4. The device of claim 1, wherein the outlet is in a first direction from the first inlet,
wherein the first distribution channel comprises a channel that extends in a second direction and a third direction, wherein the second direction crosses the first direction, and the third direction is opposite to the second direction,
wherein the outlet is in a fourth direction from the second inlet, the fourth direction being opposite to the first direction, and
wherein the second distribution channel comprises a channel that extends in the second direction and the third direction.

5. The device of claim 1, wherein the outlet is in a first direction from the first inlet, and
wherein the first distribution channel comprises:
a first channel that extends in a second direction and a third direction, wherein the second direction crosses the first direction, and the third direction is opposite to the second direction; and
a second channel that is connected to the first inlet by the first channel, the second channel extending in the first direction and a fourth direction that is opposite to the first direction.

6. The device of claim 1, wherein the second distribution channel is symmetrical with respect to the first distribution channel.

7. A semiconductor system comprising:
a semiconductor device; and
a cold plate on the semiconductor device and configured to cool the semiconductor device,
wherein the cold plate comprises:
a first inlet configured to receive a first portion of a working fluid, the working fluid configured to cool the semiconductor device;
a second inlet configured to receive a second portion of the working fluid;
an outlet configured to output the first portion and the second portion of the working fluid from the cold plate;
a first distribution channel that connects the first inlet and the outlet; and
a second distribution channel that connects the second inlet and the outlet.

8. The semiconductor system of claim 7, wherein the semiconductor device comprises:
at least one semiconductor chip; and
at least one photonic engine configured to send at least one optical signal to the at least one semiconductor chip,
wherein the first distribution channel is configured to cool the at least one semiconductor chip and the at least one photonic engine via the first portion of the working fluid, and
wherein the second distribution channel is configured to cool the at least one semiconductor chip and the at least one photonic engine via the second portion of the working fluid.

9. The semiconductor system of claim 7, wherein the semiconductor device comprises:
at least one semiconductor chip; and
at least one photonic engine configured to send at least one optical signal to the at least one semiconductor chip,
wherein the first distribution channel extends from the first inlet to the outlet such as to at least partially overlap with the at least one photonic engine and the at least one semiconductor chip, and
wherein the second distribution channel extends from the second inlet to the outlet such as to at least partially overlap with the at least one photonic engine and the at least one semiconductor chip.

10. The semiconductor system of claim 7, wherein the first inlet is at a first side of the cold plate,
wherein the second inlet is at a second side of the cold plate, opposite to the first side, and
wherein the outlet is between the first inlet and the second inlet.

11. The semiconductor system of claim 7, wherein the outlet is in a first direction from the first inlet, and
wherein the first distribution channel comprises a channel that extends in a second direction and a third direction, wherein the second direction crosses the first direction, and the third direction is opposite to the second direction.

12. The semiconductor system of claim 7, wherein the outlet is in a first direction from the first inlet,
wherein the first distribution channel comprises a channel that extends in a second direction and a third direction, wherein the second direction crosses the first direction, and the third direction is opposite to the second direction,
wherein the outlet is in a fourth direction from the second inlet, the fourth direction being opposite to the first direction, and
wherein the second distribution channel comprises a channel that extends in the second direction and the third direction.

13. The semiconductor system of claim 7,, wherein the outlet is in a first direction from the first inlet, and
wherein the first distribution channel comprises:
a first channel that extends in a second direction and a third direction, wherein the second direction crosses the first direction, and the third direction is opposite to the second direction; and
a second channel that is connected to the first inlet by the first channel, the second channel extending in the first direction and a fourth direction that is opposite to the first direction.

14. The semiconductor system of claim 7, wherein the second distribution channel is symmetrical with respect to the first distribution channel.

15. A method comprising:
supplying a first portion and a second portion of a working fluid into a first inlet and a second inlet of a cold plate, respectively;
cooling a semiconductor device via the first portion of the working fluid in a first distribution channel of the cold plate, and via the second portion of the working fluid in a second distribution channel of the cold plate; and
outputting the first portion and the second portion of the working fluid via an outlet of the cold plate,
wherein the first distribution channel connects the first inlet and the outlet, and the second distribution channel connects the second inlet and the outlet.

16. The method of claim 15, wherein the semiconductor device includes:
at least one semiconductor chip; and
at least one photonic engine configured to send at least one optical signal to the at least one semiconductor chip,
wherein the first distribution channel is configured to cool the at least one semiconductor chip and the at least one photonic engine via the first portion of the working fluid, and
wherein the second distribution channel is configured to cool the at least one semiconductor chip and the at least one photonic engine via the second portion of the working fluid.

17. The method of claim 15, wherein the semiconductor device includes:
at least one semiconductor chip; and
at least one photonic engine configured to send at least one optical signal to the at least one semiconductor chip,
wherein the first distribution channel extends from the first inlet to the outlet such as to at least partially overlap with the at least one photonic engine and the at least one semiconductor chip, and
wherein the second distribution channel extends from the second inlet to the outlet such as to at least partially overlap with the at least one photonic engine and the at least one semiconductor chip.

18. The method of claim 15, wherein the first inlet is at a first side of the cold plate,
wherein the second inlet is at a second side of the cold plate, opposite to the first side, and
wherein the outlet is between the first inlet and the second inlet.

19. The method of claim 15, wherein the outlet is in a first direction from the first inlet, and
wherein the first distribution channel includes a channel that extends in a second direction and a third direction, wherein the second direction crosses the first direction, and the third direction is opposite to the second direction.

20. The method of claim 15, wherein the outlet is in a first direction from the first inlet,
wherein the first distribution channel comprises a channel that extends in a second direction and a third direction, wherein the second direction crosses the first direction, and the third direction is opposite to the second direction,
wherein the outlet is in a fourth direction from the second inlet, the fourth direction being opposite to the first direction, and
wherein the second distribution channel comprises a channel that extends in the second direction and the third direction.
